(19) United States
(12) Patent Application Publication
(10) Pub. No.: US 2024/0309505 A1
(43) Pub. Date: Sep. 19, 2024

(54) DIAMOND MANUFACTURING SYSTEM, METHOD, CONTROL APPARATUS AND PROGRAM

(71) Applicant: OOKUMA DIAMOND DEVICE INC., Sapporo-shi (JP)

(72) Inventors: Takahiro YAMAGUCHI, Hokkaido (JP); Naohisa Hoshikawa, Hokkaido (JP)

(73) Assignee: OOKUMA DIAMOND DEVICE INC., Sapporo-shi (JP)

(21) Appl. No.: 18/602,805

(22) Filed: Mar. 12, 2024

(30) Foreign Application Priority Data
Mar. 14, 2023 (JP) 2023-040045

(51) Int. Cl. C23C 16/448; C01B 32/26; C23C 16/27; C25B 1/04; C25B 15/08

(52) U.S. Cl. CPC C23C 16/448; C01B 32/26; C23C 16/27; C25B 1/04; C25B 15/081; C25B 15/085

(57) ABSTRACT

A diamond manufacturing system comprises: a hydrogen gas manufacturing apparatus that manufactures hydrogen gas by electrolyzing water using electric power; a methane gas manufacturing apparatus that synthesizes the hydrogen gas manufactured by the hydrogen gas manufacturing apparatus and carbon dioxide; a hydrogen gas flow rate control valve that controls flow rate of the hydrogen gas from the hydrogen gas manufacturing apparatus; a methane gas flow rate control valve that controls flow rate of the methane gas from the methane gas manufacturing apparatus; and a diamond manufacturing apparatus that manufactures diamond using the hydrogen gas and the methane gas whose flow rates are controlled by the hydrogen gas flow rate control valve and the methane gas flow rate control valve.

### CROSS REFERENCE TO RELATED APPLICATIONS

This application is based upon and claims the benefit of the priority of Japanese patent application No. 2023-040045, filed on Mar. 14, 2023, the disclosure of which is incorporated herein in its entirety by reference thereto.

The present invention relates to a diamond manufacturing system, method, control apparatus, and program.

### BACKGROUND

### Technical Field

As a countermeasure against global warming, it is necessary to effectively use renewable energy (including natural energy) such as solar power, wind power, hydropower, geothermal heat, solar heat, atmospheric heat, other heat existing in a natural world, and biomass. Also, in order to expand the use of renewable energy, stable demand is required to accept electric power generated by renewable energy generation.

However, the electric power obtained from renewable energy generation cannot be obtained centrally and does not have high output like nuclear power generation or thermal power generation, so it is expensive and there is no stable demand destination. Also, the electric power obtained from renewable energy generation is susceptible to a natural environment and a supply thereof is unstable, so it is difficult to greatly rely on renewable energy. In other words, in the renewable energy power generation, it is difficult to supply electric power stably at a cost commensurate with demand, so there is a current situation that the government purchases electric power obtained from the renewable energy generation at a fixed price. Further, as the introduction of renewable energy power generation spreads rapidly, there is a risk that the supply amount will exceed the demand amount, so the output of renewable energy power generation is being limited or suppressed and there is also a current situation that it is not being used effectively. Therefore, it is proposed to store surplus electric power of the renewable energy generation, convert (gas conversion) the surplus electric power into fuel gas (e.g. hydrogen gas, methane gas) using P2G (Power to Gas) to store it, and generate electric power using the stored electric power or the stored fuel gas, when it is not possible to generate electric power (see, for example, Patent Literatures (PTL) 1 to 4).

PTL 1: Japanese Patent Kokai Publication No. JP2015-189721A
PTL 2: Japanese Patent Kokai Publication No. JP2018-16840A
PTL 3: Japanese Patent Kokai Publication No. JP2020-33284A
PTL 4: Japanese Patent Kokai Publication No. JP2020-63206A

### SUMMARY

The following analysis has been provided by the present inventors.

However, there are problems with electric power storage and P2G being unprofitable, and there is a current situation that the renewable energy has not been effectively used. That is, as to electric power storage, it is technologically underdeveloped, there is a current situation that there is no technology that can sufficiently store surplus electric power. As to P2G, it is also technologically underdeveloped, it requires labor costs, it uses an expensive apparatus, and the larger electric power generation facilities and gas manufacturing facilities they are generally built in rural areas far from urban areas, costs for pipeline equipment, road improvement, etc. to ship and transport the manufactured fuel gas to a consumption area are large, in the manufactured fuel gas that is more expensive and unstable than natural fuel gas, there is no stable gas demand (continuous gas consumption), and there is a current situation that the cost of the manufactured fuel gas is not commensurate with the selling price. Due to the above reasons, the effective use of renewable energy has not progressed, and in fact, about 40% of surplus electric power is wasted.

It is a main object of the present invention to provide a diamond manufacturing system, method, control apparatus, and program that can contribute to effective use of renewable energy.

A diamond manufacturing system according to a first aspect comprises: a hydrogen gas manufacturing apparatus that manufactures hydrogen gas by electrolyzing water using electric power; a methane gas manufacturing apparatus that manufactures methane gas by synthesizing the hydrogen gas manufactured by the hydrogen gas manufacturing apparatus and carbon dioxide; a hydrogen gas flow rate control valve that controls flow rate of the hydrogen gas from the hydrogen gas manufacturing apparatus; a methane gas flow rate control valve that controls flow rate of the methane gas from the methane gas manufacturing apparatus; and a diamond manufacturing apparatus that manufactures diamond using the hydrogen gas and the methane gas whose flow rates are controlled by the hydrogen gas flow rate control valve and the methane gas flow rate control valve.

A method of manufacturing diamond according to a second aspect comprises: manufacturing hydrogen gas by electrolyzing water using electric power; manufacturing methane gas by synthesizing the manufactured hydrogen gas and carbon dioxide; controlling flow rate of the manufactured hydrogen gas; controlling flow rate of the manufactured methane gas; and manufacturing diamond using the hydrogen gas and the methane gas whose flow rates are controlled.

A control apparatus according to a third aspect is configured to control all of the controllable components in the diamond manufacturing system according to the first aspect.

A program according to a fourth aspect causes a control apparatus to execute a process for controlling controllable components in the diamond manufacturing system according to the first aspect.

The program can be recorded on a computer-readable storage medium. The storage medium can be non-transitory such as semiconductor memory, hard disk, magnetic recording medium, optical recording medium, and the like. Also, the present disclosure can also be realized as a computer program product. The program is input from an input apparatus or an outside to a computer apparatus via communication interface, is stored in a storage device, drives a processor in accordance with predetermined steps or processings, can be caused to display results of processing including intermediate states as necessary in stages via a display apparatus, or can be communicated with the outside via a communication interface. A computer apparatus for this purpose, as an example, typically comprises a processor, a storage device, an input apparatus, a communication interface, and a display apparatus as necessary, which are connectable to each other by a bus.

According to the first to fourth aspects, it is possible to contribute to effective use of renewable energy.

### BRIEF DESCRIPTION OF THE DRAWINGS

FIG. 1 is a block diagram schematically showing a configuration of a diamond manufacturing system according to an example embodiment 1.

FIG. 2 is a flowchart diagram schematically showing an operation of a control apparatus of the diamond manufacturing system according to the example embodiment 1.

FIG. 3 is a block diagram schematically showing a configuration of a diamond manufacturing system according to an example embodiment 2.

FIG. 4 is a block diagram schematically showing a configuration of a diamond manufacturing system according to an example embodiment 3.

FIG. 5 is a block diagram schematically showing a configuration of a diamond manufacturing system according to an example embodiment 4.

FIG. 6 is a block diagram schematically showing a configuration of a diamond manufacturing system according to an example embodiment 5.

FIG. 7 is a block diagram schematically showing a configuration of a diamond manufacturing system according to an example embodiment 6.

FIG. 8 is a block diagram schematically showing a configuration of a diamond manufacturing system according to an example embodiment 7.

FIG. 9 is a block diagram schematically showing a configuration of a diamond manufacturing system according to an example embodiment 8.

FIG. 10 is a block diagram schematically showing a configuration of hardware resources.

### DETAILED DESCRIPTION

Hereinafter, example embodiments will be described with reference to drawings. It should be noted that when reference numerals are attached to the drawings in the present application, they are solely for a purpose of helping understanding, and are not intended to limit the example embodiments shown in the drawings. Also, the following example embodiments are only examples, and do not limit the present invention. Further, connection lines between blocks in the drawings and the like referred to in the following description include both bidirectional and unidirectional connections. The unidirectional arrows schematically show flows of main signals (data) and do not exclude bidirectionality. Furthermore, in circuit diagrams, block diagrams, internal configuration diagrams, connection diagrams, etc. disclosed in the present application, an input port and an output port exist at the input end and the output end of each connection line, respectively, although not explicitly shown. The same applies to input/output interface. The program is executed via a computer apparatus, and the computer apparatus comprises, for example, a processor, a storage device, an input apparatus, a communication interface, and a display apparatus as necessary. The computer apparatus is configured to be able to communicate with an internal or external apparatus (including computer) via the communication interface, irrespective of wired or wireless.

### Example Embodiment 1

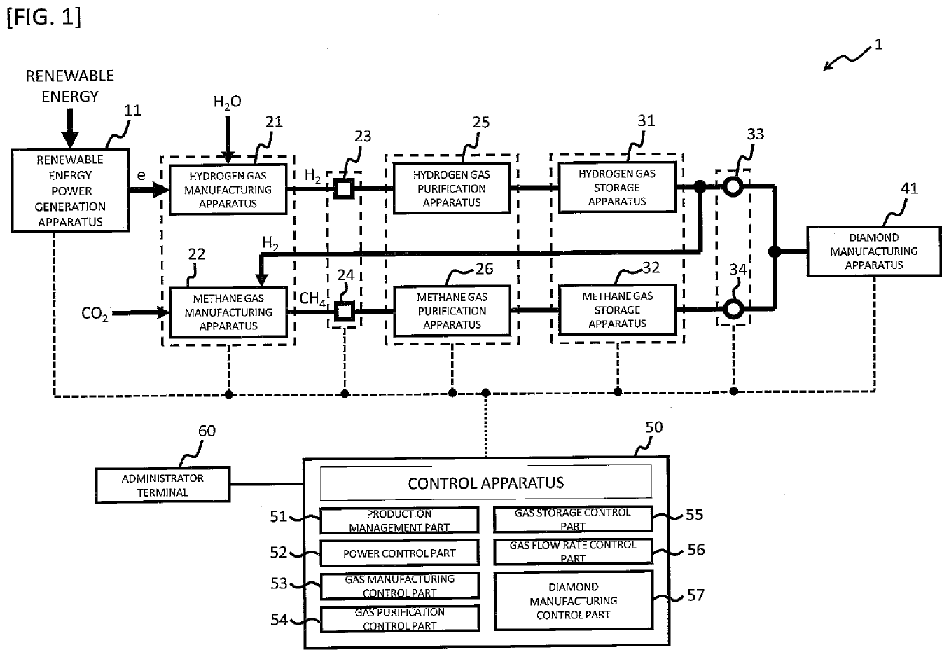

A diamond manufacturing system according to an example embodiment 1 will be explained using drawings. FIG. 1 is a block diagram schematically showing a configuration of the diamond manufacturing system according to the example embodiment 1.

The diamond manufacturing system 1 is a system for generating electric power using renewable energy; manufacturing hydrogen gas and methane gas that are raw materials for diamonds using the obtained by generating electric power; and manufacturing diamond using the manufactured hydrogen gas and methane gas as raw materials (see FIG. 1). The diamond manufacturing system 1 is configured to eliminate or minimize power transmission costs and gas transportation costs by consolidating power generation, gas manufacturing, and gas consumption within one predetermined site. The diamond manufacturing system 1 comprises: a renewable energy power generation apparatus 11; a hydrogen gas manufacturing apparatus 21; a methane gas manufacturing apparatus 22; an impurity detection sensor for hydrogen 23; an impurity detection sensor for methane 24; a hydrogen gas purification apparatus 25; a methane gas purification apparatus 26; a hydrogen gas storage apparatus 31; a methane gas storage apparatus 32; a hydrogen gas flow rate control valve 33; a methane gas flow rate control valve 34; and a diamond manufacturing apparatus 41. In the diamond manufacturing system 1, the renewable energy power generation apparatus 11, the hydrogen gas manufacturing apparatus 21, and the methane gas manufacturing apparatus 22 forms a P2G (Power to Gas) system that converts electric power into fuel gas (here, hydrogen gas and methane gas).

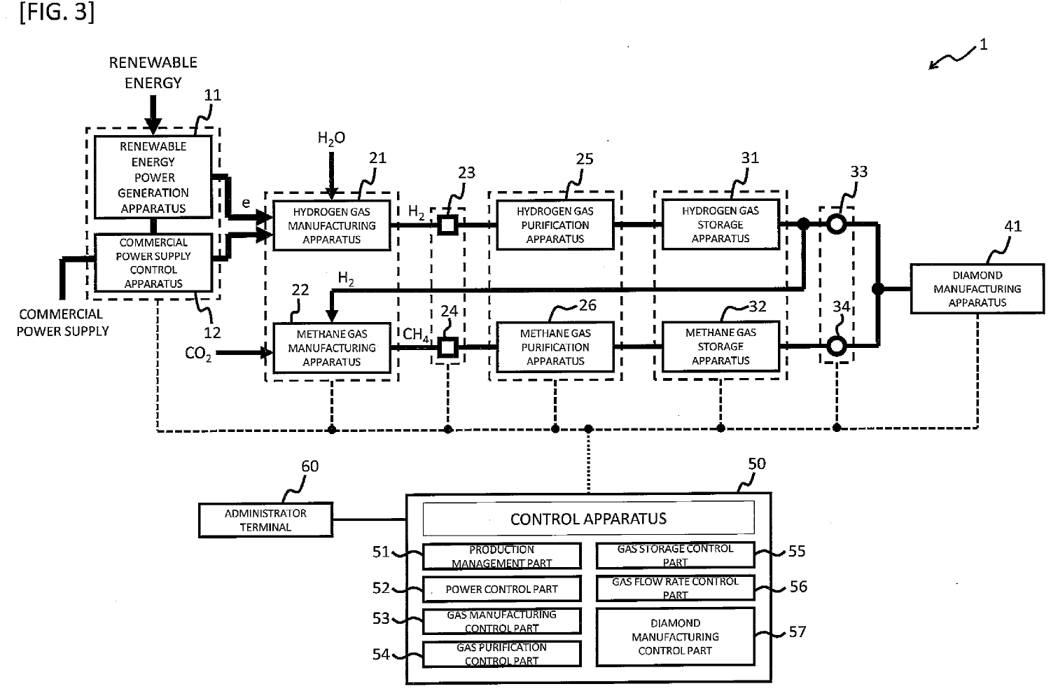

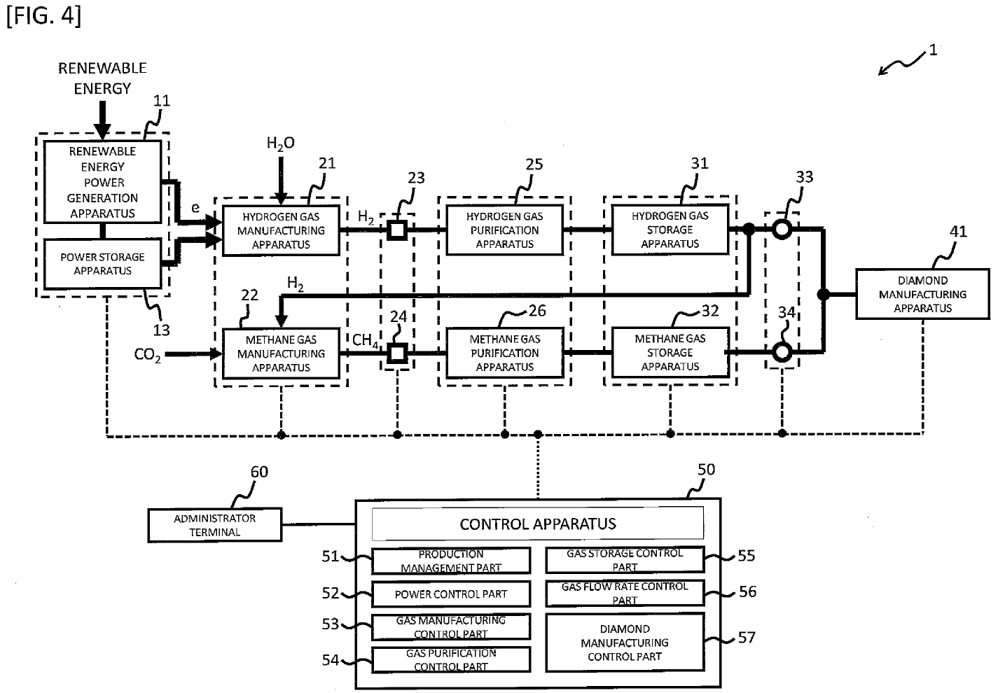

The renewable energy power generation apparatus 11 is an apparatus that generates electric power using renewable energy (see FIG. 1). As the renewable energy power generation apparatuses 11, for example, a solar power generation apparatus, a wind power generation apparatus (including an offshore wind power generation apparatus), hydroelectric power generation apparatuses (including an ocean current power generation apparatus and a wave power generation apparatus), a geothermal power generation apparatus, and a solar power generation apparatus, a thermal power generation apparatus that uses heat in the atmosphere or other natural resources, a biomass power generation apparatus, etc. can be used. The renewable energy power generation apparatus 11 can be placed in any location, but it is preferable to place it in a location where an energy source is easy to obtain depending on conditions such as natural environment and topography and is often placed at a location away from a demand area (a consumption area) generally. The electric power (e) generated by the renewable energy power generation apparatus 11 is mainly used in the hydrogen gas manufacturing apparatus 21. In case that the electric power generated by the renewable energy power generation apparatus 11 can be stably obtained exceeding the maximum power consumption of the hydrogen gas manufacturing apparatus 21, surplus electric power exceeding the maximum power consumption may be used in other apparatus (methane gas manufacturing apparatus 22, hydrogen gas purification apparatus 25, a methane gas purification apparatus 26, a diamond manufacturing apparatus 41, etc.). As to other methods of using surplus electric power, please see the following example embodiments 2 and 3 (FIGS. 3 and 4). The renewable energy power generation apparatus 11 may be controlled by a control apparatus 50.

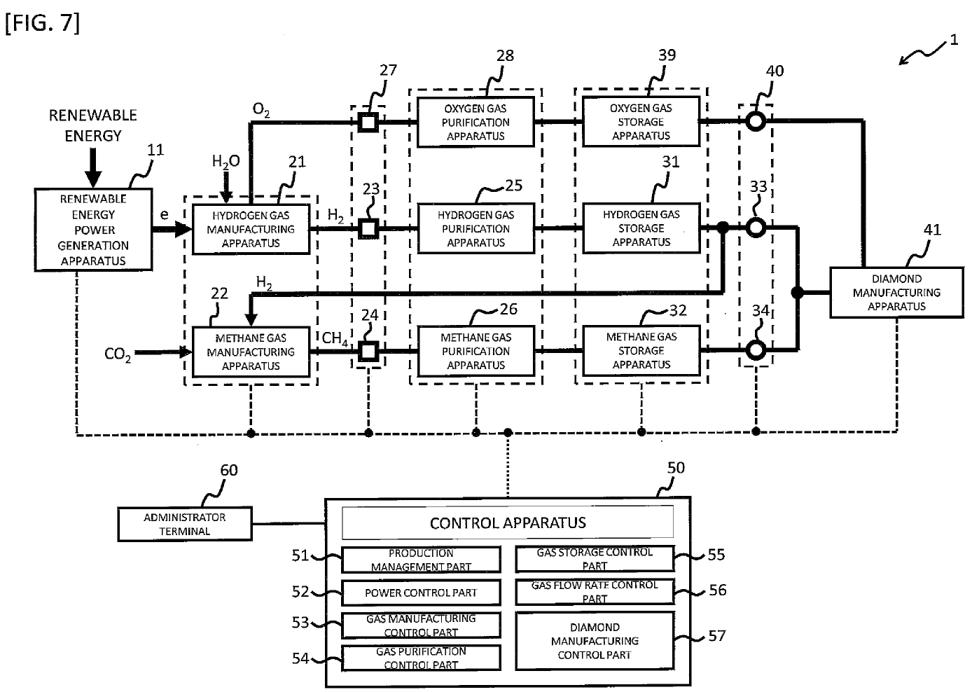

The hydrogen gas manufacturing apparatus 21 is an apparatus that manufactures hydrogen gas (H₂) (see FIG. 1). The hydrogen gas manufacturing apparatus 21 manufactures hydrogen gas by electrolyzing water using the water (H₂O) as a raw material and the electric power generated by the renewable energy power generation apparatus 11. The hydrogen gas manufactured by the hydrogen gas manufacturing apparatus 21 is transmitted to the impurity detection sensor for hydrogen 23 through a pipeline. The hydrogen gas manufactured by the hydrogen gas manufacturing apparatus 21 can be mainly used as a raw material gas for diamond and can be used as a raw material gas for methane gas. As to use of oxygen gas by-produced by the hydrogen gas manufacturing apparatus 21, please see the following example embodiment 6 (FIG. 7). The hydrogen gas manufacturing apparatus 21 can be placed in conjunction (or relation) with the renewable energy power generation apparatus 11 and is preferably placed at a location where power transmission costs can be eliminated or minimized. The hydrogen gas manufacturing apparatus 21 may be controlled by the control apparatus 50.

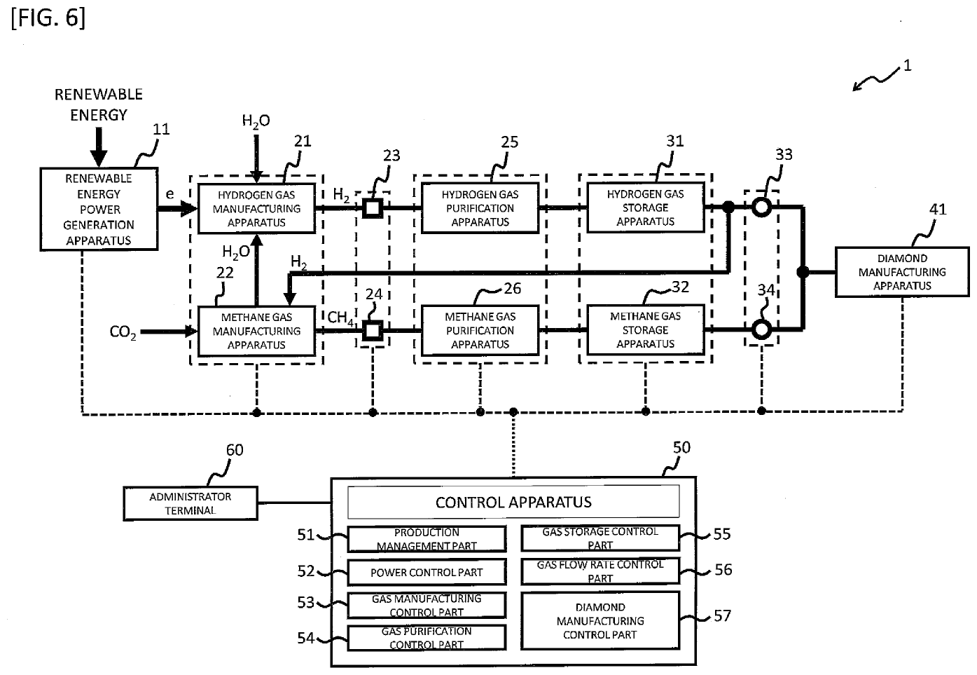

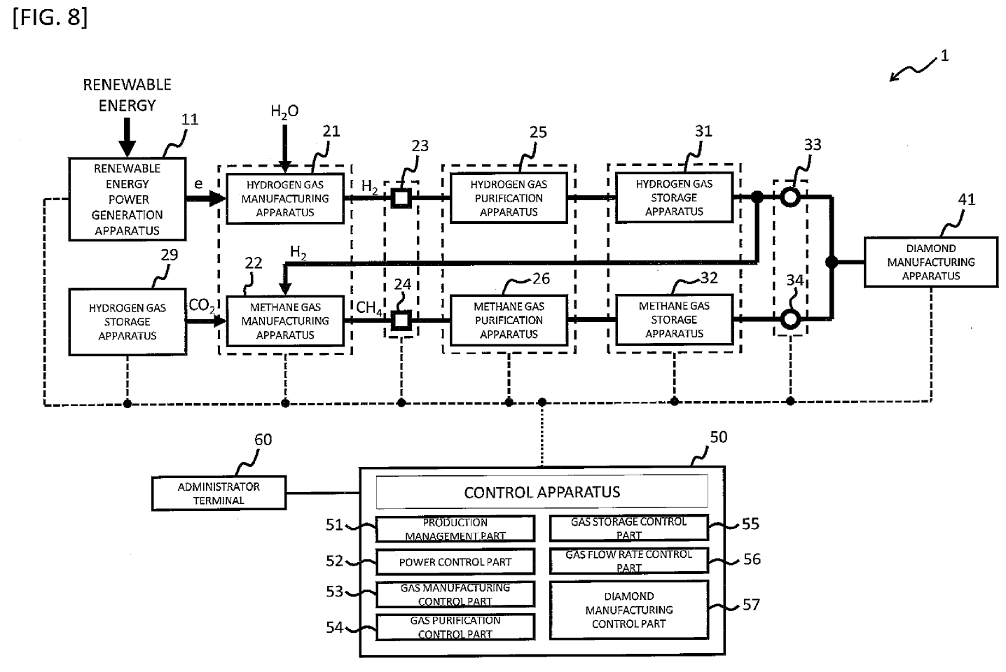

The methane gas manufacturing apparatus 22 is an apparatus that manufactures methane gas (CH₄) (see FIG. 1). The methane gas manufacturing apparatus 22 may manufacture methane gas by synthesizing carbon dioxide and hydrogen gas using, for example, carbon dioxide (CO₂) and hydrogen gas (H₂) as raw materials. As the carbon dioxide, for example, carbon dioxide collected directly from the atmosphere, or carbon dioxide collected from gas emitted from a factory, power plant, etc. if there is a factory, power plant, etc. nearby may be used (see the following example embodiment 7; see FIG. 8). As the hydrogen gas, hydrogen gas stored in the hydrogen gas storage apparatus 31 (hydrogen gas purified by the hydrogen gas purification apparatus 25 may also be used) can be used. The methane gas manufactured by the methane gas manufacturing apparatus 22 is transmitted to the impurity detection sensor for methane 24 through a pipeline. Methane gas manufactured by the methane gas manufacturing apparatus 22 can be used as raw material gas for diamond. As to use of water by-produced by the methane gas manufacturing apparatus 22, please see the following example embodiment 5 (FIG. 6). The methane gas manufacturing apparatus 22 can be placed in conjunction (or relation) with the hydrogen gas manufacturing apparatus 21. The methane gas manufacturing apparatus 22 may be controlled by the control apparatus 50.

The impurity detection sensor for hydrogen 23 is a sensor that detects impurity concentration in the hydrogen gas manufactured by the hydrogen gas manufacturing apparatus 21 (see FIG. 1). The hydrogen gas that has passed through the impurity detection sensor for hydrogen 23 is transmitted to the hydrogen gas purification apparatus 25 through a pipeline. Data on the impurity concentration in the hydrogen gas detected by the impurity detection sensor for hydrogen 23 is transmitted to the control apparatus 50.

The impurity detection sensor for methane 24 is a sensor that detects impurity concentration in the methane gas manufactured by the methane gas manufacturing apparatus 22 (see FIG. 1). The methane gas that has passed through the impurity detection sensor for methane 24 is transmitted to the methane gas purification apparatus 26 through a pipeline. Data on the impurity concentration in methane gas detected by the impurity detection sensor for methane 24 is transmitted to the control apparatus 50.

The hydrogen gas purification apparatus 25 is an apparatus that performs a purification process on the hydrogen gas manufactured by the hydrogen gas manufacturing apparatus 21 (see FIG. 1). The hydrogen gas purification apparatus 25 may be controlled by the control apparatus 50. The hydrogen gas purification apparatus 25 performs a purification process according to the impurity concentration in the hydrogen gas detected by the impurity detection sensor for hydrogen 23. The hydrogen gas purification apparatus 25 may be configured to exhaust the hydrogen gas without performing a purification process when the impurity concentration in the hydrogen gas is higher than a predetermined concentration (for example, when the hydrogen gas manufacturing apparatus 21 starts operating, stops operating, etc.). The hydrogen gas purified by the hydrogen gas purification apparatus 25 is transmitted to the hydrogen gas storage apparatus 31 and the methane gas manufacturing apparatus 22 through pipelines.

The methane gas purification apparatus 26 is an apparatus that purifies the methane gas manufactured by the methane gas manufacturing apparatus 22 (see FIG. 1). The methane gas purification apparatus 26 may be controlled by the control apparatus 50. The methane gas purification apparatus 26 performs a purification process according to the impurity concentration in the methane gas detected by the impurity detection sensor for methane 24. The methane gas purification apparatus 26 may be configured to exhaust the methane gas without performing a purification process when the impurity concentration in the methane gas is higher than a predetermined concentration (for example, when the methane gas manufacturing apparatus 22 starts operating, stops operating, etc.). The methane gas purified by the methane gas purifier 26 is transmitted to the methane gas storage apparatus 32 through a pipeline.

The hydrogen gas storage apparatus 31 is an apparatus that stores hydrogen gas (see FIG. 1). As the hydrogen gas storage apparatus 31, for example, an apparatus using a hydrogen storage material, high pressure compression, low temperature liquefaction, conversion to another substance, etc. can be used. The hydrogen gas storage apparatus 31 can perform a control and a storage amount management by the control apparatus 50. The hydrogen gas storage apparatus 31 stores the hydrogen gas purified by the hydrogen gas purification apparatus 25. The hydrogen gas stored in the hydrogen gas storage apparatus 31 can be transmitted to the hydrogen gas flow rate control valve 33 and the methane gas manufacturing apparatus 22 through pipelines.

The methane gas storage apparatus 32 is an apparatus that stores methane gas (see FIG. 1). As the methane gas storage apparatus 32, for example, an apparatus using metal organic structure adsorption, high pressure compression, low temperature liquefaction, a methane hydrate method, etc. can be used. The methane gas storage apparatus 32 can perform a control and a storage amount management by the control apparatus 50. The methane gas storage apparatus 32 stores the methane gas purified by the methane gas purification apparatus 26. The methane gas stored in the methane gas storage apparatus 32 can be transmitted to the methane gas flow rate control valve 34 through a pipeline.

The hydrogen gas flow rate control valve 33 is a valve that controls flow rate of the hydrogen gas from the hydrogen gas storage apparatus 31 (see FIG. 1). As the hydrogen gas flow rate control valve 33, for example, an electric flow rate control valve comprising a solenoid, a motor, etc. can be used. The hydrogen gas flow rate control valve 33 is controlled by the control apparatus 50. The hydrogen gas whose flow rate is controlled by the hydrogen gas flow rate control valve 33 is mixed with the methane gas whose flow rate is controlled by the methane gas flow rate control valve 34 through a pipeline, and the mixed gas is supplied to the diamond manufacturing apparatus 41.

The methane gas flow rate control valve 34 is a valve that controls flow rate of the methane gas from the methane gas storage apparatus 32 (see FIG. 1). As the methane gas flow rate control valve 34, for example, an electric flow rate control valve comprising a solenoid, a motor, etc. can be used. The methane gas flow rate control valve 34 is controlled by the control apparatus 50. The methane gas whose flow rate is controlled by the methane gas flow rate control valve 34 is mixed with the methane gas whose flow rate is controlled by the hydrogen gas flow rate control valve 33 through a pipeline, and the mixed gas is supplied to the diamond manufacturing apparatus 41.

The diamond manufacturing apparatus 41 is an apparatus that manufactures diamond (artificial diamonds) using hydrogen gas and methane gas (see FIG. 1). As the diamond manufacturing apparatus 41, an apparatus using a vapor phase synthesis method can be used, for example, a CVD (Chemical Vapor Deposition) apparatus using a CVD method such as a hot filament CVD method, a microwave plasma CVD method, or an optical CVD method can be used. In the diamond manufacturing apparatus 41, the mixed gas of the hydrogen gas and the methane gas is supplied into a chamber from the hydrogen gas flow rate control valve 33 and the methane gas flow rate control valve 34. The diamond manufacturing apparatus 41 can be configured to chemically react the mixed gas in the chamber by physical effects such as plasma, heat, light, etc. to form a diamond film synthesized by the chemical reaction on a surface of a processed object (for example, a substrate, etc.) in the chamber, or grow a diamond on a diamond seed crystal in the chamber. The diamond manufacturing apparatus 41 may collect and reuse exhaust gas (including by-product gas, by-products, etc.) that has not turned into diamonds out of the mixed gas. The diamond manufacturing apparatus 41 can be not only a configuration in which one diamond manufacturing apparatus exists but also a configuration in which multiple diamond manufacturing apparatuses exist in parallel in paths after the hydrogen gas flow rate control valve 33 and the methane gas flow rate control valve 34. The diamond manufacturing apparatus 41 can be used to manufacture diamond parts in, for example, a jewelry, a semiconductor element, a processing tool, a wear resistant tools, a heat sink, a bonding tool, a window material, an anvil, and the like. The diamond manufacturing apparatus 41 may be controlled by the control apparatus 50.

The control apparatus 50 is an apparatus that controls the renewable energy power generation apparatus 11, the hydrogen gas manufacturing apparatus 21, the methane gas manufacturing apparatus 22, the impurity detection sensor for hydrogen 23, the impurity detection sensor for methane 24, the hydrogen gas purification apparatus 25, the methane gas purification apparatus 26, the hydrogen gas storage apparatus 31, the methane gas storage apparatus 32, the hydrogen gas flow rate control valve 33, the methane gas flow rate control valve 34, and the diamond manufacturing apparatus 41 (hereinafter, the renewable energy power generation apparatus 11 to the diamond manufacturing apparatus 41 are referred to as “control objects”), As the control apparatus 50, an apparatus comprising a computer function can be used, for example, a personal computer, a server, or the like can be used. The control apparatus 50 is communicably connected to the control objects via a network. The control apparatus 50 may be placed in a remote location away from the control objects. The control apparatus 50 may exist virtually on a cloud. By executing a predetermined stored program, the control apparatus 50 can have a configuration that virtually comprises a production management part 51, a power control part 52, a gas manufacturing control part 53, a gas purification control part 54, a gas storage control part 55, a gas flow rate control part 56 and a diamond manufacturing control part 57.

The production management part 51 is a function part that acquires a diamond production plan and manages the diamond production amount (see FIG. 1). The production management part 51 acquires a diamond production plan from an administrator terminal 60 through operation by an administrator. The diamond production plan is a plan for producing diamonds, and can be a plan including data such as, for example, a type of diamond, a diamond production amount plan, a selling price of diamond, a manufacturing cost of diamond, a price of electric power from commercial power supply, a selling price of electric power, a price of gas, a material cost, a labor cost, and other expenses. The production management part 51 updates the inventory information when the diamond manufacturing apparatus 41 completes diamond manufacturing and feeds the inventory information back to future production plan.

The power control part 52 is a function part that controls the electric power from the renewable energy power generation apparatus 11, a commercial power supply, etc. as power sources (see FIG. 1). The power control part 52 controls output destinations of electric power generated by the renewable energy power generation apparatus 11 according to an power generation amount of the renewable energy power generation apparatus 11 based on the production plan (power price of commercial power supply, power selling price, etc.). For example, in case that the power generation amount of the renewable energy power generation apparatus 11 is less than a minimum power consumption amount of the hydrogen gas manufacturing apparatus 21, the power control part 52 can control so that the electric power generated by the renewable energy power generation apparatus 11 is not outputted toward the hydrogen gas manufacturing apparatus 21 and the electric power is used for an electric power sale, an electric power storage, or electric power for other apparatuses. Also, in case that the power generation amount of the renewable energy power generation apparatus 11 is between the minimum power consumption amount and a maximum power consumption amount of the hydrogen gas manufacturing apparatus 21, the power control part 52 can control so that the power generation amount of the renewable energy power generation apparatus 11 is output centrally toward the hydrogen gas manufacturing apparatus 21. Further, in case that the power generation amount of the renewable energy power generation apparatus 11 is more than the maximum power consumption amount of the hydrogen gas manufacturing apparatus 21, the power control part 52 can control so that the electric power generated by the renewable energy power generation apparatus 11 is outputted toward the hydrogen gas manufacturing apparatus 21 and meanwhile the electric power is used for an electric power sale, an electric power storage, or electric power for other apparatuses.

The gas manufacturing control part 53 is a function part that controls manufacturing of hydrogen gas and methane gas in the hydrogen gas manufacturing apparatus 21 and the methane gas manufacturing apparatus 22 based on the production plan and the gas storage amounts (see FIG. 1). The gas manufacturing control part 53 calculates each manufacturing amount of hydrogen gas and methane gas, so that each gas storage amount in the hydrogen gas storage apparatus 31 and the methane gas storage apparatus 32 is optimized, based on the production plan, and controls the hydrogen gas manufacturing apparatus 21 and meanwhile the methane gas manufacturing apparatus 22 based on the manufacturing amounts.

The gas purification control part 54 is a function part that controls the hydrogen gas purification apparatus 25 and the methane gas purification apparatus 26 based on the detection data from the impurity detection sensor for hydrogen 23 and the impurity detection sensor for methane 24 (see FIG. 1). In case that the impurity concentration detected by the impurity detection sensor for hydrogen 23 or the impurity detection sensor for methane 24 is higher than a predetermined concentration, the gas purification control part 54 controls to exhaust air and not to perform purification process, in the hydrogen gas purification apparatus 25 or the methane gas purification apparatus 26. In case that the impurity concentration detected by the impurity detection sensor for hydrogen 23 or the impurity detection sensor for methane 24 is less than a predetermined concentration, the gas purification control part 54 controls to perform purification process in the hydrogen gas purification apparatus 25 or the methane gas purification apparatus 26.

The gas storage control part 55 is a function part that controls input and output of hydrogen gas and methane gas stored in the hydrogen gas storage apparatus 31 and methane gas storage apparatus 32 (see FIG. 1). Since a gas concentration used differs depending on the type of diamond, the gas storage control part 55 monitors each gas storage amount in the hydrogen gas storage apparatus 31 and the methane gas storage apparatus 32 in accordance with the production plan.

The gas flow rate control part 56 is a function part that controls the hydrogen gas flow rate control valve 33 and the methane gas flow rate control valve 34 so that the mixed gas supplied to the diamond manufacturing apparatus 41 has a predetermined mixing ratio (mixing ratio corresponding to the type of diamond in the production plan) according to the type of diamond (see FIG. 1). The gas flow rate control part 56 changes a set value of the mixing ratio according to the type of diamond in the production plan.

The diamond manufacturing control part 57 is a function part that controls the diamond manufacturing apparatus 41 according to the production plan (particularly the type of diamond) and the gas storage amount (see FIG. 1). The diamond manufacturing control part 57 controls so that the diamond manufacturing apparatus 41 is caused not to operate when the storage amount of hydrogen gas or methane gas in the hydrogen gas storage apparatus 31 or the methane gas storage apparatus 32 is insufficient. The diamond manufacturing control part 57 controls so that the diamond manufacturing apparatus 41 is caused to operate when each storage amounts of hydrogen gas and methane gas in the hydrogen gas storage apparatus 31 and the methane gas storage apparatus 32 are greater than or equal to the storage amount that satisfies a production plan amount of diamond in the production plan. The diamond manufacturing control part 57 controls the diamond manufacturing apparatus 41 so that predetermined manufacturing parameters are set according to the type of diamond when the diamond manufacturing apparatus 41 operates. As the manufacturing parameters, temperature, pressure, and synthesis time, etc. in the chamber of the diamond manufacturing apparatus 41 can be mentioned. The diamond manufacturing control part 57 changes set values of the manufacturing parameters according to the type of diamond in the production plan.

The administrator terminal 60 is a terminal used by an administrator of the diamond manufacturing system 1 (see FIG. 1). As the administrator terminal 60, for example, a personal computer, a tablet terminal, a smartphone, etc. can be used. The administrator terminal 60 is communicably connected to the control apparatus 50. The administrator terminal 60 can operate information in the control apparatus 50 through operations of the administrator.

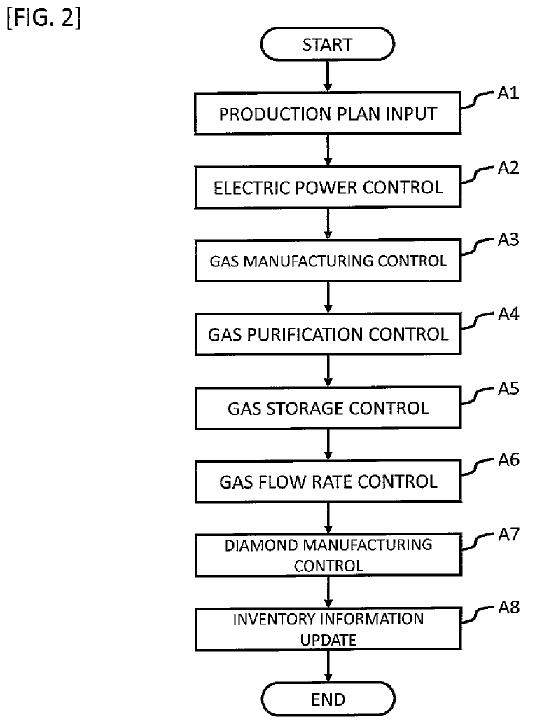

An operation of the control apparatus of the diamond manufacturing system according to the example embodiment 1 will be explained using drawings. FIG. 2 is a flowchart diagram schematically showing the operation of the control apparatus of the diamond manufacturing system according to the example embodiment 1. As to the configuration of the diamond manufacturing system, please see FIG. 1.

First, the production management part 51 of the control apparatus 50 acquires the diamond production plan from the administrator terminal 60 through operations by the administrator (step A1).

Next, the power control part 52 of the control apparatus 50 controls an output destination of electric power generated by the renewable energy power generation apparatus 11 according to the power generation amount of the renewable energy power generation apparatus 11 based on the production plan (power price of commercial power supply, electric power sales price, etc.) (step A2). For example, in case that the power generation amount of the renewable energy power generation apparatus 11 is greater than or equal to the minimum power consumption of the hydrogen gas manufacturing apparatus 21, it is controlled to output the electric power generated by the renewable energy power generation apparatus 11 toward the hydrogen gas manufacturing apparatus 21 without using the commercial power supply.

Next, the gas manufacturing control part 53 of the control apparatus 50 controls each manufacturing of hydrogen gas and methane gas in the hydrogen gas manufacturing apparatus 21 and the methane gas manufacturing apparatus 22 based on the production plan and the gas storage amounts (Step A3).

Next, the gas purification control part 54 of the control apparatus 50 controls the hydrogen gas purification apparatus 25 and the methane gas purification apparatus 26 based on the detection data from the impurity detection sensor for hydrogen 23 and the impurity detection sensor for methane 24 (step A4).

Next, the gas storage control part 55 of the control apparatus 50 controls the input and output of hydrogen gas and methane gas stored in the hydrogen gas storage apparatus 31 and the methane gas storage apparatus 32 (step A5).

Next, the gas flow rate control part 56 of the control apparatus 50 controls the hydrogen gas flow rate control valve 33 and the methane gas flow rate control valve 34 so that the mixed gas supplied to the diamond manufacturing apparatus 41 becomes a predetermined mixing ratio (mixing ratio corresponding to the type of diamond in the production plan) according to the type of diamond (step A6).

Next, the diamond manufacturing control part 57 of the control apparatus 50 controls the diamond manufacturing apparatus 41 according to the production plan (particularly the type of diamond) and the gas storage amount (step A7). Steps A2 to A7 are performed in parallel when control is started.

Finally, the production management part 51 of the control apparatus 50 updates the inventory information, when diamond manufacturing in the diamond manufacturing apparatus 41 is completed, and feeds the inventory information back to future production plan (step A8), and then ends the process.

According to the example embodiment 1, since electric power is generated using renewable energy; hydrogen gas is manufactured using the generated electric power; diamond is manufactured using the manufactured hydrogen gas and methane gas; diamonds consume a large amount of hydrogen gas; diamonds have high added value; and demand of diamonds is increasing, it is possible to contribute to effective use of renewable energy.

Also, according to the example embodiment 1, since methane is manufactured by using hydrogen, manufactured using renewable energy, and carbon dioxide, and the produced hydrogen and methane are used in manufacturing of diamonds, it is possible to consume large amounts of hydrogen and methane continuously without incurring transportation (transmission) costs, and it is possible to contribute to preventing surplus electric power from being wasted.

Also, according to the example embodiment 1, since hydrogen and methane manufactured by P2G are continuously consumed in large amounts in a manufacturing of artificial diamonds whose market size is rapidly expanding, it is possible to contribute to a technology development of P2G and contribute to promoting long term use of renewable energy.

Also, according to the example embodiment 1, since diamonds are manufactured using carbon dioxide from the atmosphere and carbon dioxide emitted from factories, power plants, etc. as raw materials for methane, carbon dioxide emissions can be reduced, carbon fixation can be promoted, and it is possible to contribute to countermeasures against global warming.

Also, according to the example embodiment 1, since diamonds with high added value and small size are manufactured using renewable energy, it is possible to contribute to ensuring profitability even when energy prices fluctuate.

Further, according to the example embodiment 1, since power generation, gas manufacturing, and gas consumption can be consolidated within one predetermined site, a diamond manufacturing system facility can be constructed in a rural area far from an urban area, and no cost of pipeline equipment, road maintenance, etc. is required. And in the long run, costs can be lower than when transporting and using natural fuel gas, so it is possible to contribute to making the costs of manufactured raw material gases commensurate with the product's selling price.

Furthermore, according to the example embodiment 1, the entire diamond manufacturing system 1 is managed and controlled by the control apparatus 50 based on the production plan, so it is possible to contribute to maintain production capacity even when it is difficult to reduce labor costs and secure personnel.

### Example Embodiment 2

A diamond manufacturing system according to the example embodiment 2 will be explained using drawings. FIG. 3 is a block diagram schematically showing a configuration of the diamond manufacturing system according to the example embodiment 2.

The example embodiment 2 is a modification of the example embodiment 1, in which a commercial power supply control apparatus 12 that controls commercial power supply is added to a power supply part of the diamond manufacturing system 1 (see FIG. 3). The commercial power supply control apparatus 12 controls the commercial power supply according to the power generation amount of the renewable energy power generation apparatus 11. The commercial power supply control apparatus 12 is electrically connected to the commercial power supply and can supply electric power from the commercial power supply to the hydrogen gas manufacturing apparatus 21. Also, the commercial power supply control apparatus 12 is electrically connected to the renewable energy power generation apparatus 11 and can supply (sell) surplus electric power of the renewable energy power generation apparatus 11 to the commercial power supply. The commercial power supply control apparatus 12 can also be configured not to use commercial power supply. The commercial power supply control apparatus 12 is controlled by control apparatus 50.

The power control part 52 of the control apparatus 50 can control the commercial power supply control apparatus 12 to supply power from the commercial power supply to the hydrogen gas manufacturing apparatus 21 when the renewable energy power generation apparatus 11 is inoperable or unstable. In case that the power generation amount of the renewable energy power generation apparatus 11 is less than the minimum power consumption of the hydrogen gas manufacturing apparatus 21, the power control part 52 can control the commercial power supply control apparatus 12 to use the electric power generated by the renewable energy power generation apparatus 11 to selling power without outputting the electric power to the hydrogen gas manufacturing apparatus 21. In case that the power generation amount of the renewable energy power generation apparatus 11 exceeds the maximum power consumption of the hydrogen gas manufacturing apparatus 21, the power control part 52 can control the commercial power supply control apparatus 12 so that the electric power generated by the renewable energy power generation apparatus 11 is sold to the commercial power supply while outputting the electric power to the hydrogen gas manufacturing apparatus 21. The power control part 52 can control the commercial power supply control apparatus 12 according to the power price of the commercial power supply, the electric power selling price of, etc. in the production plan.

The other configurations are the same as the example embodiment 1.

According to the example embodiment 2, similarly to the example embodiment 1, it is possible to contribute to effective use of renewable energy, it is possible to sell the surplus electric power of the renewable energy power generation apparatus 11 through the commercial power supply control apparatus 12 to make effective use. Also, according to the example embodiment 2, even if the power generation amount of the renewable energy power generation apparatus 11 is insufficient or unstable due to the influence of the natural environment, it is possible to continue to operate the hydrogen gas storage apparatus 31 using the commercial power supply.

### Example Embodiment 3

A diamond manufacturing system according to the example embodiment 3 will be explained using drawings. FIG. 4 is a block diagram schematically showing a configuration of the diamond manufacturing system according to the example embodiment 3.

The example embodiment 3 is a modification of the example embodiment 1, in which a power storage apparatus 13 that stores electric power (including surplus electric power) from a renewable energy power generation apparatus 11 is added to a power supply part of the diamond manufacturing system 1. The power storage apparatus 13 is capable of supplying the stored power to the hydrogen gas manufacturing apparatus 21. The power storage apparatus 13 is controlled by control apparatus 50. The power storage apparatus 13 can control to supply the electric power stored in the power storage apparatus 13 itself to the hydrogen gas manufacturing apparatus 21; to store the electric power of the energy generation apparatus 11 in the power storage apparatus 13 itself; or not to store or discharge electric power according to the power generation amount of the renewable energy power generation apparatus 11 and the power storage amount in the power storage apparatus 13.

The power control part 52 of the control apparatus 50 can control the power storage apparatus 13 to supply the electric power stored in the power storage apparatus 13 to the hydrogen gas manufacturing apparatus 21 when the renewable energy power generation apparatus 11 is inoperable or unstable. The power control part 52 can control the power storage apparatus 13 to use the electric power generated by the renewable energy power generation apparatus 11 for power storage without outputting the electric power towards the hydrogen gas manufacturing apparatus 21 when the power generation amount of the renewable energy power generation apparatus 11 is less than the minimum power consumption of the hydrogen gas manufacturing apparatus 21. The power control part 52 can control the power storage apparatus 13 to use the electric power generated by the renewable energy power generation apparatus 11 for power storage while outputting the electric power towards the hydrogen gas manufacturing apparatus 21 when the power generation amount of the renewable energy power generation apparatus 11 is more than the maximum power consumption of the hydrogen gas manufacturing apparatus 21.

The other configurations are the same as the example embodiment 1. Also, the example embodiment 3 may be applied to the example embodiment 2.

According to the example embodiment 3, similarly to the example embodiment 1, it is possible to contribute to the effective use of renewable energy, and it is possible to use effectively the surplus electric power of the renewable energy power generation apparatus 11 by storing the surplus electric power in the power storage apparatus 13.

Also, according to the example embodiment 3, even if the power generation amount of the renewable energy power generation apparatus 11 is insufficient or unstable due to the influence of the natural environment, it is possible to continue operation of the hydrogen gas storage apparatus 31 by using the stored electric power.

### Example Embodiment 4

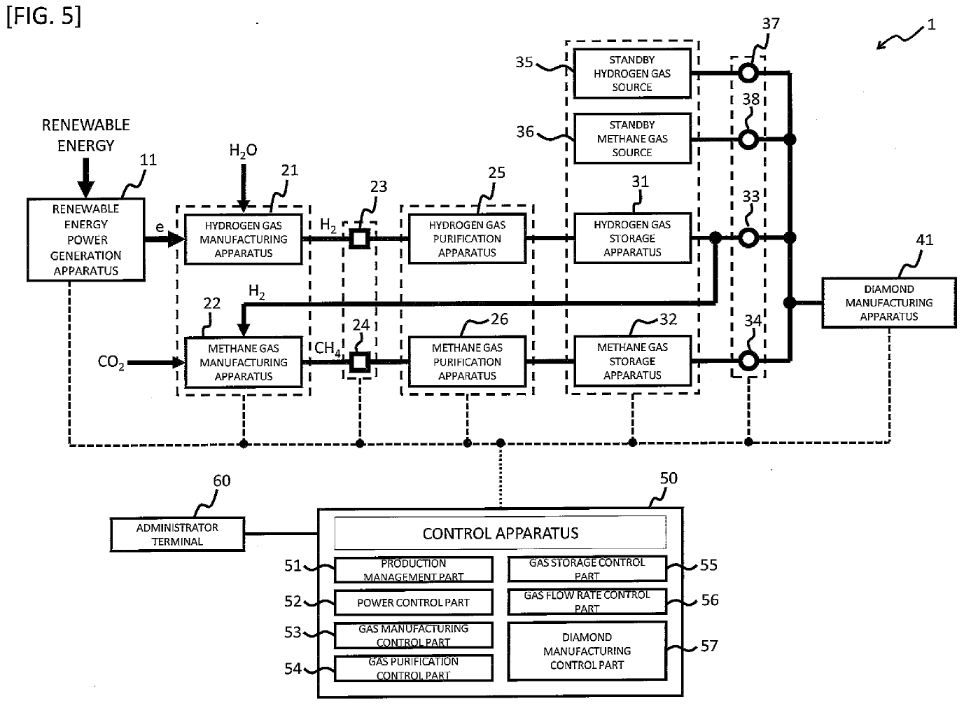

A diamond manufacturing system according to the example embodiment 4 will be described with reference to the drawings. FIG. 5 is a block diagram schematically showing a configuration of the diamond manufacturing system according to the example embodiment 4.

The example embodiment 4 is a modification of the example embodiment 1, and a standby hydrogen gas source 35, a standby methane gas source 36, a standby hydrogen gas flow rate control valve 37, and a standby methane gas flow rate control valve 38 are added so that the diamond manufacturing apparatus 41 can continue to operate even if there is a shortage of hydrogen gas or methane gas stored in the hydrogen gas storage apparatus 31 or the methane gas storage apparatus 32.

The standby hydrogen gas source 35 is a hydrogen gas source used for standby. The standby methane gas source 36 is a methane gas source used for standby.

The standby hydrogen gas flow rate control valve 37 is a valve that controls a flow rate of hydrogen gas from the standby hydrogen gas source 35. As the standby hydrogen gas flow rate control valve 37, for example, an electric flow rate control valve comprising a solenoid, a motor, etc. can be used. The standby hydrogen gas flow rate control valve 37 is controlled by the control apparatus 50. The hydrogen gas whose flow rate is controlled by the standby hydrogen gas flow rate control valve 37 joins and mixes with the methane gas whose flow rate is controlled by the methane gas flow rate control valve 34 or the standby methane gas flow rate control valve 38, and the mixed gas is supplied to the diamond manufacturing apparatus 41.

The standby methane gas flow rate control valve 38 is a valve that controls the flow rate of methane gas from the standby methane gas source 36. As the standby methane gas flow rate control valve 38, for example, an electric flow rate control valve comprising a solenoid, a motor, etc. can be used. The standby methane gas flow rate control valve 38 is controlled by the control apparatus 50. The methane gas whose flow rate is controlled by the standby methane gas flow rate control valve 38 joins and mixes with the hydrogen gas whose flow rate is controlled by the hydrogen gas flow rate control valve 33 or the standby hydrogen gas flow rate control valve 37, and the mixed gas is supplied to the diamond manufacturing apparatus 41.

The gas flow rate control part 56 of the control apparatus 50 controls the hydrogen gas flow rate control valve 33, the methane gas flow rate control valve 34, the standby hydrogen gas flow rate control valve 37, and the standby methane gas flow rate control valve 38 so that the mixed gas supplied to the diamond manufacturing apparatus 41 has a predetermined mixing ratio (mixing ratio corresponding to the type of diamond in the production plan) according to the type of diamond.

The other configurations are the same as the example embodiment 1. Also, the example embodiment 4 may be applied to the example embodiments 2 and 3.

According to the example embodiment 4, similarly to the example embodiment 1, it is possible to contribute to the effective use of renewable energy, and by having a configuration comprising the standby hydrogen gas source 35 and the standby methane gas source 36, even if there is a shortage of hydrogen gas or methane gas stored in the hydrogen gas storage apparatus 31 or the methane gas storage apparatus 32 due to an influence of environment, the operation of the diamond manufacturing apparatus 41 can be continued.

### Example Embodiment 5

A diamond manufacturing system according to the example embodiment 5 will be described with reference to the drawings. FIG. 6 is a block diagram schematically showing a configuration of the diamond manufacturing system according to the example embodiment 5.

The example embodiment 5 is a modification of the example embodiment 1 and is configured to use water by-produced in the methane gas manufacturing apparatus 22 as a raw material for hydrogen gas manufactured in the hydrogen gas manufacturing apparatus 21. All or part of the water by-produced by the methane gas manufacturing apparatus 22 may be purified and supplied to the hydrogen gas manufacturing apparatus 21. The other configurations are the same as the example embodiment 1. Also, the example embodiment 5 may be applied to the example embodiments 2 to 4.

According to the example embodiment 5, similarly to the example embodiment 1, it is possible to contribute to the effective use of renewable energy, and the water by-produced by the methane gas manufacturing apparatus 22 can be effectively used.

### Example Embodiment 6

A diamond manufacturing system according to the example embodiment 6 will be explained using drawings. FIG. 7 is a block diagram schematically showing a configuration of the diamond manufacturing system according to the example embodiment 6.

The example embodiment 6 is a modification of the example embodiment 1 and is configured to add an impurity detection sensor for oxygen 27 and an oxygen gas purification apparatus 28, an oxygen gas storage apparatus 39, and an oxygen gas flow rate control valve 40 so that the oxygen by-produced in the hydrogen gas production device 21 is used as a cleaning gas for the diamond manufacturing apparatus 41 (chamber).

The impurity detection sensor for oxygen 27 is a sensor that detects impurity concentration in the oxygen gas produced as a by-product in the hydrogen gas manufacturing apparatus 21. The oxygen gas that has passed through the impurity detection sensor for oxygen 27 is transmitted to the oxygen gas purification apparatus 28 through a pipeline. Data on the impurity concentration in the oxygen gas detected by the impurity detection sensor for oxygen 27 is transmitted to the control apparatus 50.

The oxygen gas purification apparatus 28 is an apparatus that purifies the oxygen gas produced as a by-product in the hydrogen gas manufacturing apparatus 21. The oxygen gas purification apparatus 28 may be controlled by the control apparatus 50. The oxygen gas purification apparatus 28 performs a purification process on oxygen gas according to the impurity concentration in the oxygen gas detected by the impurity detection sensor for oxygen 27. The oxygen gas purification apparatus 28 may be configured to exhaust the oxygen gas without performing a purification process when the impurity concentration in the oxygen gas is a predetermined concentration or more (for example, when the hydrogen gas manufacturing apparatus 21 starts operating, stops operating, etc.). The oxygen gas purified by the oxygen gas purification apparatus 28 is transmitted to the oxygen gas storage apparatus 39 through a pipeline.

The oxygen gas storage apparatus 39 is an apparatus that stores oxygen gas. As the oxygen gas storage apparatus 39, for example, an apparatus using an oxygen storage (absorbing) material, high pressure compression, low temperature liquefaction, conversion to another substance, etc. can be used. The oxygen gas storage apparatus 39 can be controlled and manage the storage amount by the control apparatus 50. The oxygen gas storage apparatus 39 stores oxygen gas purified by the oxygen gas purification apparatus 28. The oxygen gas stored in the oxygen gas storage apparatus 39 can be transmitted to the oxygen gas flow rate control valve 40 through a pipeline.

The oxygen gas flow rate control valve 40 is a valve that controls the flow rate of oxygen gas from the oxygen gas storage apparatus 39. As the oxygen gas flow rate control valve 40, for example, an electric flow rate control valve comprising a solenoid, a motor, etc. can be used. The oxygen gas flow rate control valve 40 is controlled by the control apparatus 50. The oxygen gas whose flow rate is controlled by the oxygen gas flow rate control valve 40 is supplied to the diamond manufacturing apparatus 41.

The gas purification control part 54 of the control apparatus 50 controls the oxygen gas purification apparatus 28 based on the detection data from the impurity detection sensor for oxygen 27. In case that the impurity concentration detected by the impurity detection sensor for oxygen 27 is a predetermined concentration or more, the gas purification control part 54 controls the oxygen gas purification apparatus 28 to exhaust the gas without performing purification process. In case that the impurity concentration detected by the impurity detection sensor for oxygen 27 is less than a predetermined concentration, the gas purification control part 54 controls the oxygen gas purification apparatus 28 to perform purification process.

The gas storage control part 55 of the control apparatus 50 controls the input and output of oxygen gas stored in the oxygen gas storage apparatus 39.

The gas flow rate control part 56 of the control apparatus 50 controls the oxygen gas flow rate control valve 40 so that the oxygen gas supplied to the diamond manufacturing apparatus 41 has a predetermined flow rate.

The diamond manufacturing control part 57 of the control apparatus 50 controls the diamond manufacturing apparatus 41 by setting parameters for cleaning when stopping the operation of the diamond manufacturing apparatus 41 and cleaning the diamond manufacturing apparatus 41. As the cleaning parameters, for example, a temperature, a pressure, cleaning time, etc. in the chamber of the diamond manufacturing apparatus 41 can be used.

The oxygen gas whose flow rate is controlled by the oxygen gas flow rate control valve 40 is supplied to the chamber of the diamond manufacturing apparatus 41, generates oxygen plasma, causes a chemical reaction between the generated oxygen plasma and carbon etc. attached to the inner wall of the chamber, etc., removes carbon and the like, and is exhausted from the diamond manufacturing apparatus 41.

The other configurations are the same as the example embodiment 1. Also, the example embodiment 6 may be applied to the example embodiments 2 to 5.

According to the example embodiment 6, similarly to the example embodiment 1, it is possible to contribute to the effective use of renewable energy, and the oxygen by-produced by the hydrogen gas manufacturing apparatus 21 can be effectively used.

### Example Embodiment 7

A diamond manufacturing system according to the example embodiment 7 will be explained using drawings. FIG. 8 is a block diagram schematically showing a configuration of the diamond manufacturing system according to the example embodiment 7.

The example embodiment 7 is a modification of the example embodiment 1 and is configured to add a carbon dioxide recovery apparatus 29 which recovers carbon dioxide from the atmosphere or carbon dioxide from gas exhausted from carbon dioxide generating sources such as factories and power plants and supplies the carbon dioxide to the methane gas manufacturing apparatus 22. The carbon dioxide recovery apparatus 29 can be controlled by the control apparatus 50. The gas manufacturing control part 53 of the control apparatus 50 controls the recovery of carbon dioxide in the carbon dioxide recovery apparatus 29 based on the production plan and the gas storage amount.

The other configurations are the same as the example embodiment 1. Also, the example embodiment 7 may be applied to the example embodiments 2 to 6.

According to the example embodiment 7, similarly to the example embodiment 1, it is possible to contribute to the effective use of renewable energy, and carbon dioxide from the atmosphere or carbon dioxide exhausted from factories, power plants, etc. is recovered and diamonds are manufactured using the recovered carbon dioxide for a raw material of methane, so carbon dioxide emission reduction and carbon fixation are promoted, and it is possible to contribute to measures against global warming.

### Example Embodiment 8

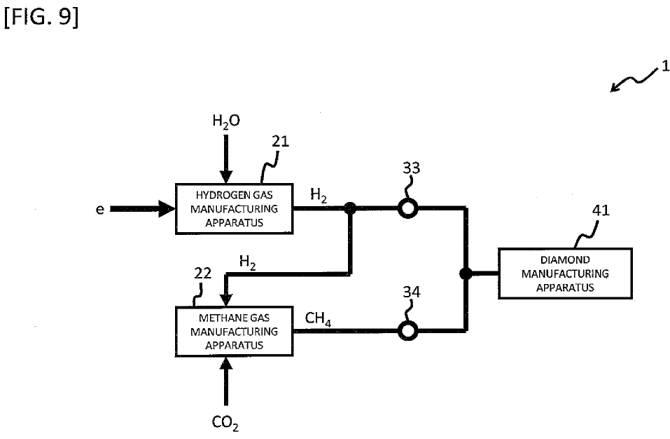

A diamond manufacturing system according to the example embodiment 8 will be explained using drawings. FIG. 9 is a block diagram schematically showing a configuration of the diamond manufacturing system according to the example embodiment 8.

The diamond manufacturing system 1 is a system that manufactures hydrogen gas and methane gas as raw materials for a diamond using electric power and manufactures diamond using the manufactured hydrogen gas and methane gas as raw materials. The diamond manufacturing system 1 comprises a hydrogen gas manufacturing apparatus 21, a methane gas manufacturing apparatus 22, a hydrogen gas flow rate control valve 33, a methane gas flow rate control valve 34, and a diamond manufacturing apparatus 41.

The hydrogen gas manufacturing apparatus 21 manufactures hydrogen gas by electrolyzing water using electric power. The methane gas manufacturing apparatus 22 manufactures methane gas by synthesizing hydrogen gas manufactured by the hydrogen gas manufacturing apparatus 21 and carbon dioxide. The hydrogen gas flow rate control valve 33 controls flow rate of the hydrogen gas from the hydrogen gas manufacturing apparatus 21. The methane gas flow rate control valve 34 controls flow rate of the methane gas from the methane gas manufacturing apparatus 22. The diamond manufacturing apparatus 41 manufactures diamond using hydrogen gas and methane gas whose flow rates are controlled by the hydrogen gas flow rate control valve 33 and the methane gas flow rate control valve 34.

According to the example embodiment 8, since electric power is generated using renewable energy; hydrogen gas is manufactured using the generated electric power; diamond is manufactured using the manufactured hydrogen gas and methane gas; diamonds consume a large amount of hydrogen gas; diamonds have high added value; and demand of diamonds is increasing, it is possible to contribute to effective use of renewable energy by using electric power generated using renewable energy as electric power.

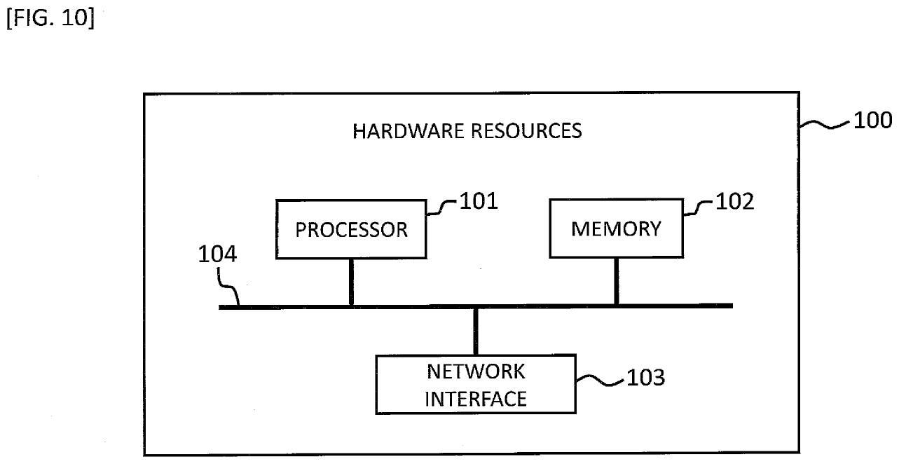

Note that the control apparatuses according to the example embodiments 1 to 7 can be configured by so-called hardware resources (information processing apparatuses, computers), and those comprising the configuration shown in FIG. 10 can be used. For example, the hardware resource 100 comprises a processor 101, a memory 102, a network interface 103, etc., which are interconnected by an internal bus 104.

Note that the configuration shown in FIG. 10 is not intended to limit the hardware configuration of the hardware resources 100. The hardware resource 100 may include hardware (for example, an input/output interface) that is not shown. Alternatively, the number of units such as the processors 101 included in the apparatus is not limited to the example shown in FIG. 10; for example, a plurality of processors 101 may be included in the hardware resources 100. As the processor 101, for example, a CPU (Central Processing Unit), a MPU (Micro Processor Unit), a GPU (Graphics Processing Unit), etc. can be used.

As the memory 102, for example, RAM (Random Access Memory), ROM (Read Only Memory), HDD (Hard Disk Drive), SSD (Solid State Drive), etc. can be used.

As the network interface 103, for example, a LAN (Local Area Network) card, a network adapter, a network interface card, etc. can be used.

The functions of the hardware resources 100 are realized by the processing modules described above. The processing modules are realized, for example, by the processor 101 executing a program stored in the memory 102. Also, the program can be updated by downloading via a network or by using a storage medium storing the program. Further, the processing module may be realized by a semiconductor chip. That is, the functions performed by the processing module may be realized by executing software on some kind of hardware.

A part or all of the above example embodiments may be described as the following Modes but is not limited to the following.

### [Mode 1]

A diamond manufacturing system, comprising:
a hydrogen gas manufacturing apparatus that manufactures hydrogen gas by electrolyzing water using electric power;
a methane gas manufacturing apparatus that manufactures methane gas by synthesizing the hydrogen gas manufactured by the hydrogen gas manufacturing apparatus and carbon dioxide;
a hydrogen gas flow rate control valve that controls flow rate of the hydrogen gas from the hydrogen gas manufacturing apparatus;
a methane gas flow rate control valve that controls flow rate of the methane gas from the methane gas manufacturing apparatus; and
a diamond manufacturing apparatus that manufactures diamond using the hydrogen gas and the methane gas whose flow rates are controlled by the hydrogen gas flow rate control valve and the methane gas flow rate control valve.

### [Mode 2]

The diamond manufacturing system according to Mode 1, further comprising a renewable energy power generation apparatus that uses renewable energy to generate electric power,
wherein the hydrogen gas manufacturing apparatus uses the electric power generated by the renewable energy power generation apparatus as the electric power.

### [Mode 3]

The diamond manufacturing system according to Mode 2, wherein the renewable energy power generation apparatus is a solar power generation apparatus that generates electric power using sunlight.

### [Mode 4]

The diamond manufacturing system according to any one of Modes 1 to 3, further comprising:
a hydrogen gas storage apparatus that stores the hydrogen gas manufactured by the hydrogen gas manufacturing apparatus; and
a methane gas storage apparatus that stores the methane gas manufactured by the methane gas manufacturing apparatus,
wherein the hydrogen gas flow rate control valve controls the flow rate of the hydrogen gas from the hydrogen gas storage apparatus, and
wherein the methane gas flow rate control valve controls the flow rate of the methane gas from the methane gas storage apparatus.

### [Mode 5]

The diamond manufacturing system according to Mode 4, further comprising:
a hydrogen gas purification apparatus that purifies the hydrogen gas manufactured by the hydrogen gas manufacturing apparatus;
a methane gas purification apparatus that purifies the methane gas manufactured by the methane gas manufacturing apparatus;
wherein the hydrogen gas storage apparatus stores the hydrogen gas purified by the hydrogen gas purification apparatus, and
wherein the methane gas storage apparatus stores the methane gas purified by the methane gas purification apparatus.

### [Mode 6]

The diamond manufacturing system according to Mode 5, further comprising:
an impurity detection sensor for hydrogen that detects impurity concentration in the hydrogen gas manufactured by the hydrogen gas manufacturing apparatus;
an impurity detection sensor for methane that detects impurity concentration in the methane gas manufactured by the methane gas manufacturing apparatus,
wherein the hydrogen gas purification apparatus purifies the hydrogen gas depending on the impurity concentration detected by the impurity detection sensor for hydrogen, and
wherein the methane gas purification apparatus purifies the methane gas depending on the impurity concentration detected by the impurity detection sensor for methane.

### [Mode 7]

The diamond manufacturing system according to any one of Modes 2 to 6, further comprising a commercial power supply control apparatus that is electrically connected to a commercial power supply, the renewable energy power generation apparatus, and the hydrogen gas manufacturing apparatus, and that controls the commercial power supply,
wherein the commercial power supply control apparatus controls the commercial power supply in one way of selected from the group consisting of: supplying electric power of the commercial power supply to the hydrogen gas manufacturing apparatus, supplying the electric power of the renewable energy power generation apparatus to the commercial power supply, and not using the commercial power supply, depending on power generation amount of the renewable energy power generation apparatus.

### [Mode 8]

The diamond manufacturing system according to any one of Modes 2 to 7, further comprising a power storage apparatus electrically connected to the renewable energy power generation apparatus and the hydrogen gas manufacturing apparatus and configured to be capable of storing the electric power from the renewable energy power generation apparatus, wherein the power storage apparatus controls in one way of selected from the group consisting of: supplying the electric power stored in the power storage apparatus to the hydrogen gas manufacturing apparatus, storing the electric power from the energy power generation apparatus, and not storing and discharging the electric power, depending on power generation amount of the renewable energy power generation apparatus and a power storage amount in the power storage apparatus.

### [Mode 9]

The diamond manufacturing system according to any one of Modes 1 to 8, further comprising:
a standby hydrogen gas source;
a standby methane gas source;
a standby hydrogen gas flow rate control valve that controls flow rate of the hydrogen gas from the standby hydrogen gas source; and
a standby methane gas flow rate control valve that controls flow rate of the methane gas from the standby methane gas source,
wherein the diamond manufacturing apparatus is configured to be capable of manufacturing the diamond using the hydrogen gas and the methane gas whose flow rates are controlled by the standby hydrogen gas flow rate control valve and the standby methane gas flow rate control valve.

### [Mode 10]

The diamond manufacturing system according to any one of Modes 1 to 9, wherein the hydrogen gas manufacturing apparatus manufactures the hydrogen gas by electrolyzing the water containing water by-produced by the methane gas manufacturing apparatus.

### [Mode 11]

The diamond manufacturing system according to any one of Modes 1 to 10, further comprising:
an impurity detection sensor for oxygen that detects impurity concentration in oxygen gas by-produced by the hydrogen gas manufacturing apparatus;
an oxygen gas purification apparatus that purifies the oxygen gas by-produced by the hydrogen gas manufacturing apparatus depending on impurity concentration in the oxygen gas detected by the impurity detection sensor for oxygen;
an oxygen gas storage apparatus that stores oxygen gas purified by the oxygen gas purification apparatus; and
an oxygen gas flow rate control valve that controls flow rate of the oxygen gas from the oxygen gas storage apparatus,
wherein when cleaning the diamond manufacturing apparatus itself, the diamond manufacturing apparatus cleans itself using the oxygen gas whose flow rate is controlled by the oxygen gas flow rate control valve.

### [Mode 12]

The diamond manufacturing system according to any one of Modes 1 to 11, further comprising a carbon dioxide recovery apparatus that recovers carbon dioxide from the atmosphere or gas emitted from carbon dioxide generation source,
wherein the methane gas manufacturing apparatus uses the carbon dioxide from the carbon dioxide recovery apparatus as the carbon dioxide.

### [Mode 13]

The diamond manufacturing system according to any one of Modes 1 to 12, wherein all of components in the diamond manufacturing system are placed in one predetermined site.

### [Mode 14]

The diamond manufacturing system according to any one of claims 1 to 13, further comprising a control apparatus configured to control all of the controllable components in the diamond manufacturing system.

### [Mode 15]

A method of manufacturing diamond, comprising: manufacturing hydrogen gas by electrolyzing water using electric power;
manufacturing methane gas by synthesizing the manufactured hydrogen gas and carbon dioxide;
controlling flow rate of the manufactured hydrogen gas;
controlling flow rate of the manufactured methane gas; and
manufacturing diamond using the hydrogen gas and the methane gas whose flow rates are controlled.

### [Mode 16]

The method of manufacturing diamond according to Mode 15, further comprising generating electric power using renewable energy,
wherein in the manufacturing the hydrogen gas, the electric power generated in the generating electric power is used as the electric power.

### [Mode 17]

The method of manufacturing diamond according to Mode 15 or 16, wherein all of steps in the method are performed within one predetermined site.

### [Mode 18]

A control apparatus, configured to control all of the controllable components in the diamond manufacturing system according to any one of Modes 1 to 13.

### [Mode 19]

A program, causing a control apparatus to execute a process for controlling controllable components in the diamond manufacturing system according to any one of Modes 1 to 13.

It should be noted that each disclosure of the above PTLs is incorporated herein by reference and can be used as the basis or part of the present invention as necessary. Within the framework of the entire disclosure of the present invention (including claims and drawings), modifications and adjustments of the example embodiments or examples are possible based on the basic technical concept thereof further. Also, various combinations or selections (if necessary not selection) of various disclosure elements (including each element of each claim, each element of each example embodiment or example, each element of each drawing, etc.) within the framework of the entire disclosure of the present invention are possible. That is, the present invention naturally includes various variations and modifications that can be made by one skilled in the art according to the entire disclosure including the claims and drawings, and the technical concept. Further, with regard to numerical values and numerical ranges described in the present application, it is deemed that any intermediate values, sub-numerical values and sub-ranges thereof are described even if not specified. Furthermore, it is deemed that each disclosure matter of the above-cited document and the matter using a part or all of the present invention as a part of the disclosure of the present invention in accordance with the concept of the present invention if necessary in combination with the matters described in the present document are included in (belong to) the disclosure matter of the present application.

### REFERENCE SIGNS LIST

1 Diamond manufacturing system
11 Renewable energy power generation apparatus
12 Commercial power supply control apparatus
13 Power storage apparatus
21 Hydrogen gas manufacturing apparatus
22 Methane gas manufacturing apparatus
23 Impurity detection sensor for hydrogen
24 Impurity detection sensor for methane
25 Hydrogen gas purification apparatus
26 Methane gas purification apparatus
27 Impurity detection sensor for oxygen
28 Oxygen gas purification apparatus
29 Carbon dioxide recovery apparatus
31 Hydrogen gas storage apparatus
32 Methane gas storage apparatus
33 Hydrogen gas flow rate control valve
34 Methane gas flow rate control valve
35 Standby hydrogen gas source
36 Standby methane gas source
37 Standby hydrogen gas flow rate control valve
38 Standby methane gas flow rate control valve
39 Oxygen gas storage apparatus
40 Oxygen gas flow rate control valve
41 Diamond manufacturing apparatus
50 Control apparatus
51 Production management part
52 Power control part
53 Gas manufacturing control part
54 Gas purification control part
55 Gas storage control part
56 Gas flow rate control part
57 Diamond manufacturing control part
60 Administrator terminal
100 Hardware resources

### 101 Processor

### 102 Memory

103 Network interface

### 104 Internal bus

What is claimed is:

1. A diamond manufacturing system, comprising:
a hydrogen gas manufacturing apparatus that manufactures hydrogen gas by electrolyzing water using electric power;
methane gas manufacturing apparatus that manufactures methane gas by synthesizing the hydrogen gas manufactured by the hydrogen gas manufacturing apparatus and carbon dioxide;
a hydrogen gas flow rate control valve that controls flow rate of the hydrogen gas from the hydrogen gas manufacturing apparatus;
a methane gas flow rate control valve that controls flow rate of the methane gas from the methane gas manufacturing apparatus; and
a diamond manufacturing apparatus that manufactures diamond using the hydrogen gas and the methane gas whose flow rates are controlled by the hydrogen gas flow rate control valve and the methane gas flow rate control valve.

2. The diamond manufacturing system according to claim 1, further comprising a renewable energy power generation apparatus that uses renewable energy to generate electric power,
wherein the hydrogen gas manufacturing apparatus uses the electric power generated by the renewable energy power generation apparatus as the electric power.

3. The diamond manufacturing system according to claim 2, wherein the renewable energy power generation apparatus is a solar power generation apparatus that generates electric power using sunlight.

4. The diamond manufacturing system according to claim 1, further comprising:
a hydrogen gas storage apparatus that stores the hydrogen gas manufactured by the hydrogen gas manufacturing apparatus; and
a methane gas storage apparatus that stores the methane gas manufactured by the methane gas manufacturing apparatus,
wherein the hydrogen gas flow rate control valve controls the flow rate of the hydrogen gas from the hydrogen gas storage apparatus, and
wherein the methane gas flow rate control valve controls the flow rate of the methane gas from the methane gas storage apparatus.

5. The diamond manufacturing system according to claim 4, further comprising:
a hydrogen gas purification apparatus that purifies the hydrogen gas manufactured by the hydrogen gas manufacturing apparatus;
a methane gas purification apparatus that purifies the methane gas manufactured by the methane gas manufacturing apparatus;
wherein the hydrogen gas storage apparatus stores the hydrogen gas purified by the hydrogen gas purification apparatus, and
wherein the methane gas storage apparatus stores the methane gas purified by the methane gas purification apparatus.

6. The diamond manufacturing system according to claim 5, further comprising:
an impurity detection sensor for hydrogen that detects impurity concentration in the hydrogen gas manufactured by the hydrogen gas manufacturing apparatus;
an impurity detection sensor for methane that detects impurity concentration in the methane gas manufactured by the methane gas manufacturing apparatus,
wherein the hydrogen gas purification apparatus purifies the hydrogen gas depending on the impurity concentration detected by the impurity detection sensor for hydrogen, and
wherein the methane gas purification apparatus purifies the methane gas depending on the impurity concentration detected by the impurity detection sensor for methane.

7. The diamond manufacturing system according to claim 2, further comprising a commercial power supply control apparatus that is electrically connected to a commercial power supply, the renewable energy power generation apparatus, and the hydrogen gas manufacturing apparatus, and that controls the commercial power supply,
wherein the commercial power supply control apparatus controls the commercial power supply in one way of selected from the group consisting of: supplying electric power of the commercial power supply to the hydrogen gas manufacturing apparatus, supplying the electric power of the renewable energy power generation apparatus to the commercial power supply, and not using the commercial power supply, depending on power generation amount of the renewable energy power generation apparatus.

8. The diamond manufacturing system according to claim 2, further comprising a power storage apparatus electrically connected to the renewable energy power generation apparatus and the hydrogen gas manufacturing apparatus and configured to be capable of storing the electric power from the renewable energy power generation apparatus,
wherein the power storage apparatus controls in one way of selected from the group consisting of: supplying the electric power stored in the power storage apparatus to the hydrogen gas manufacturing apparatus, storing the electric power from the energy power generation apparatus, and not storing and discharging the electric power, depending on power generation amount of the renewable energy power generation apparatus and a power storage amount in the power storage apparatus.

9. The diamond manufacturing system according to claim 1, further comprising:
a standby hydrogen gas source;
a standby methane gas source;
a standby hydrogen gas flow rate control valve that controls flow rate of the hydrogen gas from the standby hydrogen gas source; and
a standby methane gas flow rate control valve that controls flow rate of the methane gas from the standby methane gas source,
wherein the diamond manufacturing apparatus is configured to be capable of manufacturing the diamond using the hydrogen gas and the methane gas whose flow rates are controlled by the standby hydrogen gas flow rate control valve and the standby methane gas flow rate control valve.

10. The diamond manufacturing system according to claim 1, wherein the hydrogen gas manufacturing apparatus manufactures the hydrogen gas by electrolyzing the water containing water by-produced by the methane gas manufacturing apparatus.

11. The diamond manufacturing system according to claim 1, further comprising:
an impurity detection sensor for oxygen that detects impurity concentration in oxygen gas by-produced by the hydrogen gas manufacturing apparatus;
an oxygen gas purification apparatus that purifies the oxygen gas by-produced by the hydrogen gas manufacturing apparatus depending on impurity concentration in the oxygen gas detected by the impurity detection sensor for oxygen;
an oxygen gas storage apparatus that stores oxygen gas purified by the oxygen gas purification apparatus; and
an oxygen gas flow rate control valve that controls flow rate of the oxygen gas from the oxygen gas storage apparatus,
wherein when cleaning the diamond manufacturing apparatus itself, the diamond manufacturing apparatus cleans itself using the oxygen gas whose flow rate is controlled by the oxygen gas flow rate control valve.

12. The diamond manufacturing system according to claim 1, further comprising a carbon dioxide recovery apparatus that recovers carbon dioxide from the atmosphere or gas emitted from carbon dioxide generation source,
wherein the methane gas manufacturing apparatus uses the carbon dioxide from the carbon dioxide recovery apparatus as the carbon dioxide.

13. The diamond manufacturing system according to claim 1, wherein all of components in the diamond manufacturing system are placed in one predetermined site.

14. The diamond manufacturing system according to claim 1, further comprising a control apparatus configured to control all of the controllable components in the diamond manufacturing system.

15. The diamond manufacturing system according to claim 2, further comprising:
a hydrogen gas storage apparatus that stores the hydrogen gas manufactured by the hydrogen gas manufacturing apparatus; and
a methane gas storage apparatus that stores the methane gas manufactured by the methane gas manufacturing apparatus,
wherein the hydrogen gas flow rate control valve controls the flow rate of the hydrogen gas from the hydrogen gas storage apparatus, and
wherein the methane gas flow rate control valve controls the flow rate of the methane gas from the methane gas storage apparatus.

16. A method of manufacturing diamond, comprising:
manufacturing hydrogen gas by electrolyzing water using electric power;
manufacturing methane gas by synthesizing the manufactured hydrogen gas and carbon dioxide;
controlling flow rate of the manufactured hydrogen gas;
controlling flow rate of the manufactured methane gas; and
manufacturing diamond using the hydrogen gas and the methane gas whose flow rates are controlled.

17. The method of manufacturing diamond according to claim 16, further comprising generating electric power using renewable energy,
wherein in the manufacturing the hydrogen gas, the electric power generated in the generating electric power is used as the electric power.

18. The method of manufacturing diamond according to claim 16, wherein all of processings in the method are performed within one predetermined site.

19. A control apparatus, configured to control all of the controllable components in the diamond manufacturing system according to claim 1.

20. A non-transitory computer readable recording medium storing a program, causing a control apparatus to execute a process for controlling controllable components in the diamond manufacturing system according to claim 1.
